(19) United States
(12) Patent Application Publication
(10) Pub. No.: US 2025/0069995 A1
(43) Pub. Date: Feb. 27, 2025

(54) SEMICONDUCTOR DEVICE AND MANUFACTURING METHOD THEREOF

(71) Applicant: REALTEK SEMICONDUCTOR CORP., Hsinchu (TW)

(72) Inventor: Nai-Jen Hsuan, Hsinchu (TW)

(73) Assignee: REALTEK SEMICONDUCTOR CORP., Hsinchu (TW)

(21) Appl. No.: 18/802,281

(22) Filed: Aug. 13, 2024

Related U.S. Application Data
(60) Provisional application No. 63/578,874, filed on Aug. 25, 2023.

(30) Foreign Application Priority Data
Jan. 12, 2024 (TW) 113101449

(51) Int. Cl. H01L 23/495; H01L 21/48; H01L 21/56; H01L 23/00; H01L 23/31; H01L 23/552

(52) U.S. Cl. CPC H01L 23/49531; H01L 21/4825; H01L 21/565; H01L 23/3107; H01L 23/49541; H01L 23/49575; H01L 23/552; H01L 24/16; H01L 24/48; H01L 24/81; H01L 24/85; H01L 2224/16245; H01L 2224/48225; H01L 2224/48245; H01L 2224/81815; H01L 2924/3011; H01L 2924/3025

(57) ABSTRACT

A semiconductor device includes a plurality of leads, a lower die, a plurality of bumps, a plurality of flip-chip solder pads, an upper die, a plurality of metal connecting pillars, and a metal wire bonding layer. Each of the leads has a first end and a second end. The leads include a plurality of first leads, a plurality of second leads, and a plurality of third leads. The first ends of the first leads are defined as a die-bonding region. The lower die is correspondingly disposed on the die-bonding region. The flip-chip solder pads are respectively disposed on the first ends of the first leads. The upper die is disposed on the lower die. The metal connecting pillars respectively stand on the first ends of the second leads. The metal wire bonding layer is disposed between the upper die and the lower die.

### CROSS-REFERENCES TO RELATED APPLICATIONS

This application claims the benefit of U.S. provisional application Ser. No. 63/578,874, filed on Aug. 25, 2023 and claims the priority of patent application No. 113101449 filed in Taiwan, R.O.C. on Jan. 12, 2024. The entirety of the above-mentioned patent applications are hereby incorporated by references herein and made a part of the specification.

### BACKGROUND

### Technical Field

The present invention relates to a packaging structure that can reduce power ripples and electromagnetic interference (EMI), and in particular relates to a semiconductor device and a manufacturing method thereof.

### Related Art

In wire bonding packages known to the inventor, the power integrity and signal integrity are affected by power ripples due to the impedance of the wire and internal leads. As the length of the wire increases, so does the impedance, leading to a greater impact of power ripples. Therefore, the wire bonding packages often have design difficulties due to excessive wire length. As a result, as known to the inventor, most chip packages containing high-speed signals with stringent requirements on signal and power integrity are flip chip packages which are considered to have better signal integrity and power integrity.

However, the lead frames of the flip-chip packages are more expensive than the lead frames of the wire bonding packages, and the heat dissipation effect of the lead frame of the flip-chip package is not as good as the heat dissipation effect of the lead frame of the wire-bonded package. Furthermore, the lead frames of the flip-chip packages are often in short supply in the market.

### SUMMARY

In some embodiments, a semiconductor device comprises a plurality of leads, a lower die, a plurality of bumps, a plurality of flip-chip solder pads, an upper die, a plurality of metal connecting pillars, and a metal wire bonding layer. Each of the leads has a first end and a second end. The leads comprise a plurality of first leads, a plurality of second leads, and a plurality of third leads. The first ends of the first leads are defined as a die-bonding region. The first leads, the second leads, and the third leads extend in a direction away from the die-bonding region. The lower die is correspondingly disposed on the die-bonding region. The lower die has an active surface. The bumps are disposed on the active surface. The flip-chip solder pads are respectively disposed on the first ends of the first leads. The lower die is directly soldered to the flip-chip solder pads through the bumps so as to be electrically connected to the first leads. The upper die corresponds to the die-bonding region and is disposed on the lower die. One side of the upper die opposite to the lower die has a plurality of first contacts and a plurality of second contacts. The first contacts are wire-bonded to the first ends of the third leads. The metal connecting pillars respectively stand on the first ends of the second leads. The metal wire bonding layer is disposed between the upper die and the lower die and is disposed on the metal connecting pillars. The second contacts are wire-bonded to the metal wire bonding layer.

In some embodiments, the metal wire bonding layer is a metal plate.

In some embodiments, the metal wire bonding layer comprises an insulating layer, a first conductive trace, a second conductive trace, and a plurality of conductive vias. The first conductive trace is on an upper surface of the insulating layer. The second contacts are wire-bonded to the first conductive trace. The second conductive trace is on a lower surface of the insulating layer and is coupled to the metal connecting pillars. The plurality of conductive vias penetrate the insulating layer and are coupled between the first conductive trace and the second conductive trace.

In some embodiments, the second contacts are a plurality of power contacts, a plurality of ground contacts, or a combination of the power contacts and the ground contacts.

In some embodiments, the semiconductor device further comprises a package. The package encloses the leads, the lower die, the bumps, the flip-chip solder pads, the upper die, the metal connecting pillars, and the metal wire bonding layer.

In some embodiments, the flip-chip solder pads comprise a plurality of first solder pads and a plurality of second solder pads. The bumps comprise a plurality of first bumps and a plurality of second bumps. Each of the first solder pads is configured to be directly soldered to a corresponding one of the first bumps. Each of the second solder pads is configured to be directly soldered to a corresponding one of the second bumps. A height of any of the second solder pads is less than a height of any of the first solder pads. A height of any of the second bumps is greater than a height of any of the first bumps.

In some embodiments, a length of each of the first leads is greater than a length of each of the third leads. A length of each of the second leads is greater than the length of each of the third leads.

In some embodiments, a manufacturing method of semiconductor device comprises: providing a lead frame, wherein the lead frame comprises a plurality of leads, each of the leads has a first end and a second end, the leads comprise a plurality of first leads, a plurality of second leads and a plurality of third leads, the first ends of the first leads are defined as a die-bonding region, and the leads extend in a direction away from the die-bonding region; forming a plurality of flip-chip solder pads on the first ends of the first leads respectively; forming a plurality of metal connecting pillars on the first ends of the second leads respectively, wherein each of the metal connecting pillars is disposed on a corresponding one of the second leads; soldering a multi-die module to the flip-chip solder pads, wherein the multi-die module comprises an upper die, a lower die, and a metal wire bonding layer, the metal wire bonding layer is disposed on the lower die and the metal connecting pillars, the upper die is disposed on the metal wire bonding layer, and one side of the upper die opposite to the metal wire bonding layer has a plurality of contacts; wire-bonding a plurality of first contacts among the contacts to the metal wire bonding layer; and wire-bonding a plurality of second contacts among the contacts to the first ends of the third leads.

In some embodiments, the steps of soldering the multi-die module to the flip-chip solder pads comprises: forming a plurality of bumps corresponding to the positions of the flip-chip solder pads on an active surface of the lower die; contacting the bumps on the lower die to the flip-chip solder pads respectively; and performing a reflow procedure so that each of the flip-chip solder pads is directly soldered to a corresponding one of the bumps.

In some embodiments, the manufacturing method of semiconductor device further comprises forming a package to enclose the lead frame, the multi-die module, and the metal connecting pillars.

To sum up, any embodiment of the semiconductor device or the manufacturing method of semiconductor device can reduce noise on the power-ground loop while providing electromagnetic interference (EMI) shielding, thereby achieving higher signal and power integrity.

### BRIEF DESCRIPTION OF THE DRAWINGS

The disclosure will become more fully understood from the detailed description given herein below for illustration only, and thus not limitative of the disclosure, wherein:

FIG. 1 illustrates a cross-sectional schematic view of an embodiment of a semiconductor device.

FIG. 2 illustrates a cross-sectional schematic view of another embodiment of the semiconductor device.

FIG. 3 illustrates a cross-sectional schematic view of yet another embodiment of the semiconductor device.

FIG. 4 illustrates a schematic view of the embodiment of the semiconductor device.

FIG. 5 illustrates a top view of the embodiment of the semiconductor device.

FIG. 6 illustrates a top view of the lead frame in FIG. 5.

FIG. 7 illustrates a top view of the lead frame and the lower die of the semiconductor device in FIG. 5.

FIG. 8 illustrates a cross-sectional schematic view of still yet another embodiment of the semiconductor device.

FIG. 9 illustrates a schematic view of an embodiment of a metal wire bonding layer.

FIG. 10 illustrates a top view of another embodiment of the lead frame.

FIG. 11A illustrates a cross-sectional schematic view of an embodiment of a flip-chip solder pad and a bump.

FIG. 11B illustrates a cross-sectional schematic view of another embodiment of the flip-chip solder pad and the bump.

FIG. 12 illustrates a bottom view of an embodiment of the lower die.

FIG. 13 illustrates a flowchart of an embodiment of a manufacturing method of semiconductor device.

FIG. 14A to FIG. 14F illustrate schematic views of the steps of the embodiment of the method of semiconductor device.

### DETAILED DESCRIPTION

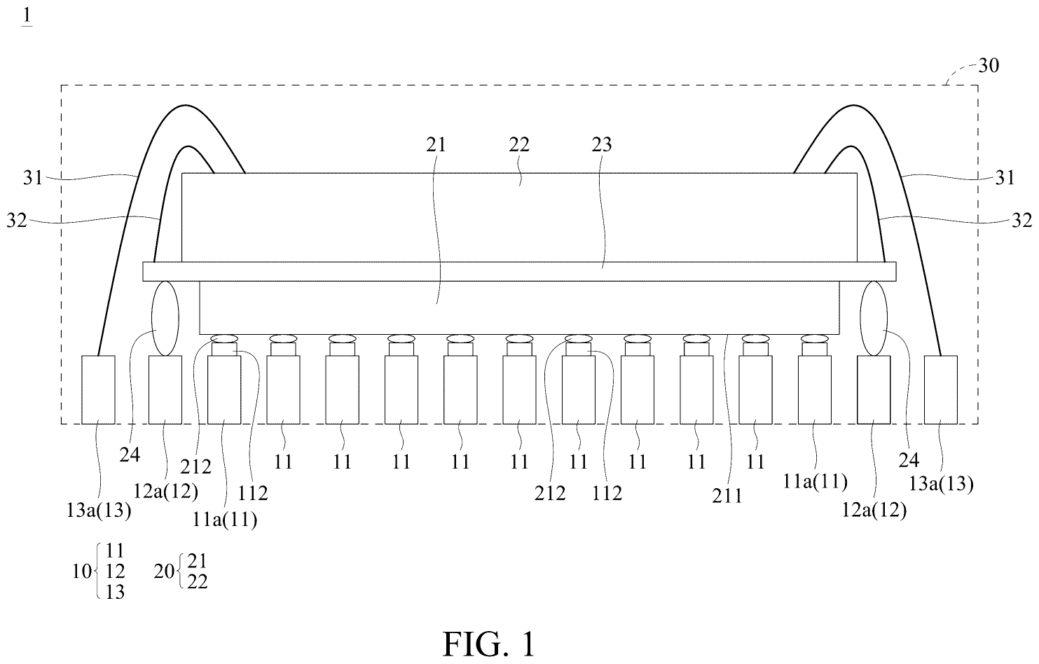

Please refer to FIG. 1 and FIG. 5 to FIG. 7. A semiconductor device 1 comprises a lead frame, a plurality of dies 20, and a metal wire bonding layer 23. The lead frame comprises a plurality of leads 10 and a plurality of metal connecting pillars 24. The dies 20 comprise one or more lower dies 21 and one or more upper dies 22. Each of the leads 10 has a first end 11a/12a/13a and a second end 11b/12b/13b. The leads 10 comprise a plurality of first leads 11, a plurality of second leads 12, and a plurality of third leads 13. The first ends 11a of the first leads 11 are defined as a die-bonding region 2. The metal wire bonding layer 23 is disposed between the upper die 22 and the lower die 21. In other words, in some embodiments, the lower die 21, the metal wire bonding layer 23, and the upper die 22 are sequentially stacked on the die-bonding region 2.

The lower surface of the lower die 21 (hereinafter referred to as an active surface 211) is the active surface of the die 21. A plurality of bumps 212 are disposed on the active surface 211. A plurality of flip-chip solder pads 112 are respectively disposed on the first ends 11a of the first leads 11. The lower die 21 is directly soldered to the flip-chip solder pads 112 through the bumps 212 so as to be electrically connected to the first leads 11.

One side of the upper die 22 opposite to the lower die 21 has a plurality of first contacts 221 and a plurality of second contacts 222. In other words, in some embodiments, the lower surface of the upper die 22 is attached to (or adhered to) the upper surface of the metal wire bonding layer 23. The upper surface of the upper die 22 has a plurality of first contacts 221 and a plurality of second contacts 222. The first contacts 221 are wire-bonded to the first ends 13a of the third leads 13. The second contacts 222 are wire-bonded to the metal wire bonding layer 23 through wires 32. In other words, in some embodiments, from a top view perspective, the upper die 22 does not completely cover the metal wire bonding layer 23, that is, the edge of the distribution range of the metal wire bonding layer 23 slightly exceeds the edge of the distribution range of the upper die 22. In some embodiments, the size of the top view profile of the metal wire bonding layer 23 is greater than the size of the top view profile of the upper die 22. In some embodiments, in the case that the dies 20 comprise multiple upper dies 22, the size of the top view profile of the metal wire bonding layer 23 is greater than the size of the top view profile formed by all of the upper dies 22.

The metal connecting pillars 24 respectively stand on the first ends 12a of the second leads 12. A first end of each of the metal connecting pillars 24 is coupled to the metal wire bonding layer 23, and a second end of each of the metal connecting pillars 24 is coupled to a corresponding one of the second leads 12. In other words, in some embodiments, each of the metal connecting pillars 24 is sandwiched between the metal wire bonding layer 23 and the corresponding one of the second leads 12. Therefore, the upper die 22 is electrically connected to the second leads 12 through the wires 32, the metal wire bonding layer 23, and the metal connecting pillars 24.

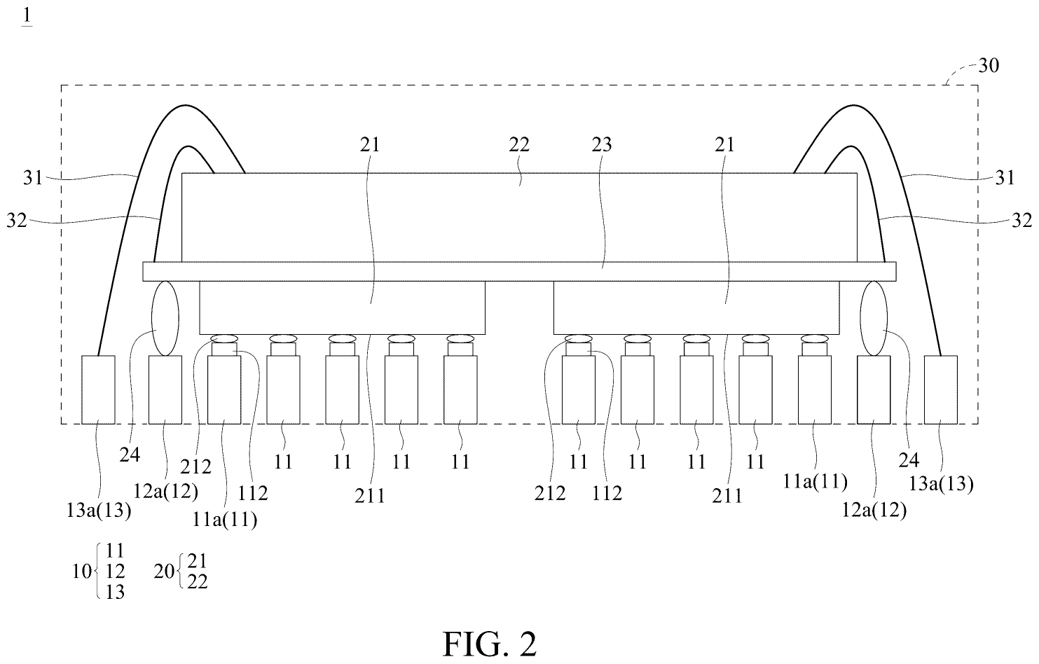

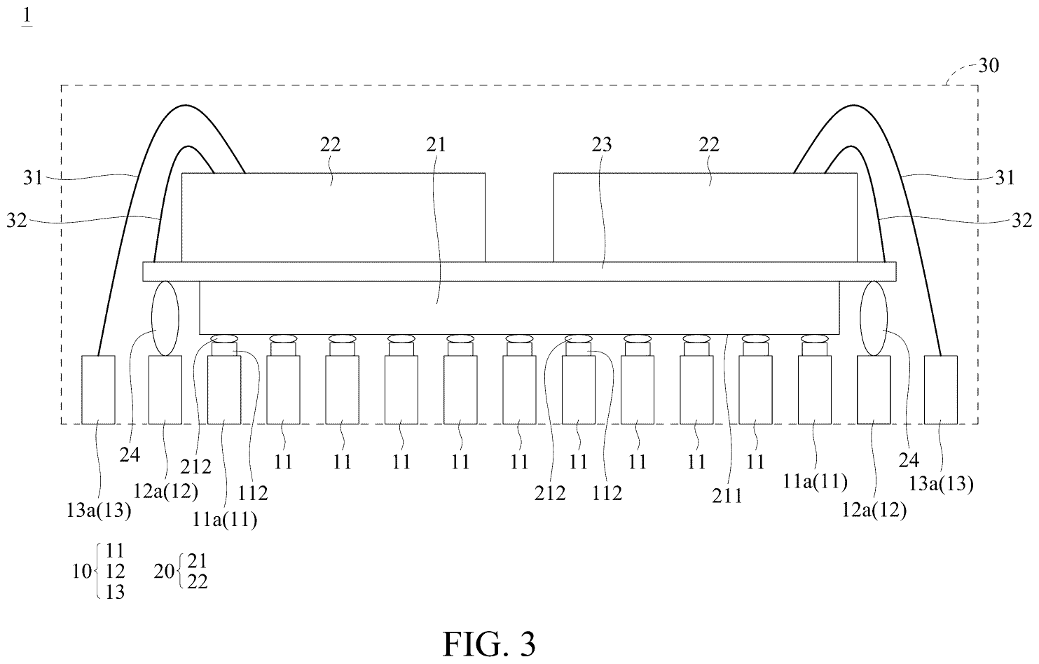

It should be noted that FIG. 1 only illustrates one lower die 21 and one upper die 22, but the present disclosure is not limited thereto. The semiconductor device 1 may be designed to have multiple lower dies 21 and/or multiple upper dies 22, as shown in FIG. 2 and FIG. 3, depending on different demands.

In some embodiments, the semiconductor device 1 further comprises a package 30. The package 30 encloses the leads 10, the lower die 21, the bumps 212, the flip-chip solder pads 112, the upper die 22, the metal connecting pillars 24, and the metal wire bonding layer 23.

According to some embodiments, the purpose of enclosing the leads 10, the lower die 21, the bumps 212, the flip-chip solder pads 112, the upper die 22, the metal connecting pillars 24, and the metal wire bonding layer 23 with the package 30 is to prevent air and moisture from entering the semiconductor device 1. In some embodiments, the material of the package 30 may be selected according to the impedance system to which the semiconductor device 1 is applied. In some embodiments, the material of the package 30 may be but not limited to common epoxy resin packaging material or aluminum oxide epoxy resin packaging material.

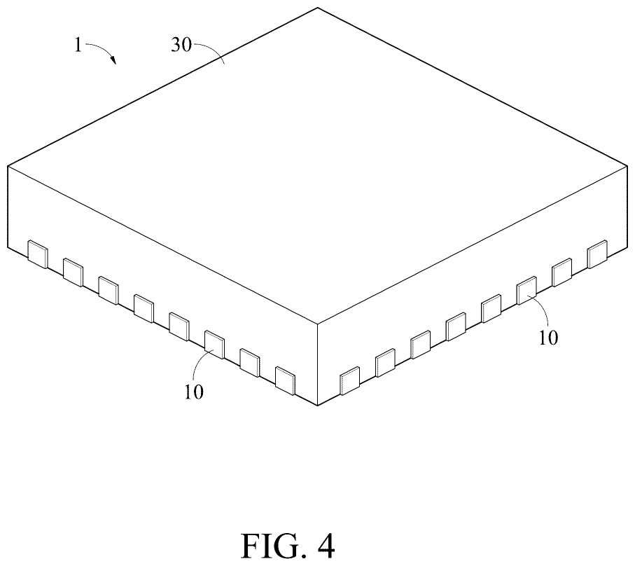

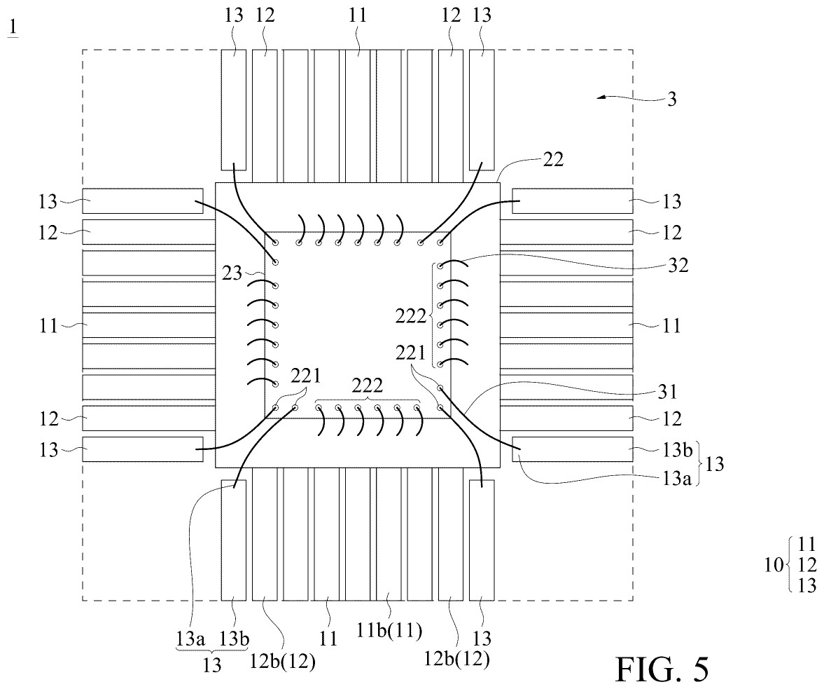

In some embodiments, the semiconductor device 1 may adopt a QFN (Quad Flat No leads) packaging structure (as shown in FIG. 4 and FIG. 5), but the present disclosure is not limited thereto. In order to clearly explain the detailed structure of the semiconductor device 1, the following description takes the semiconductor device 1 as the QFN package structure as an example.

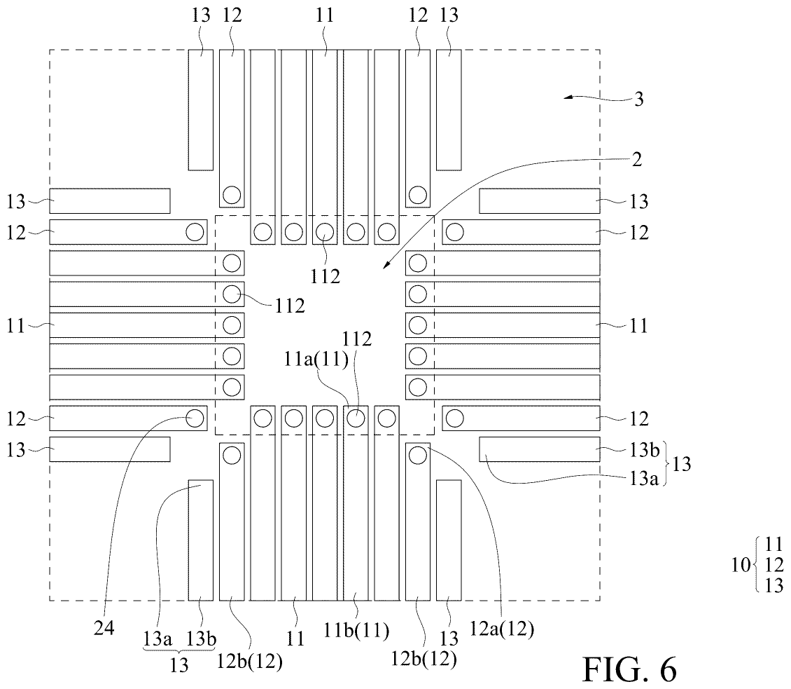

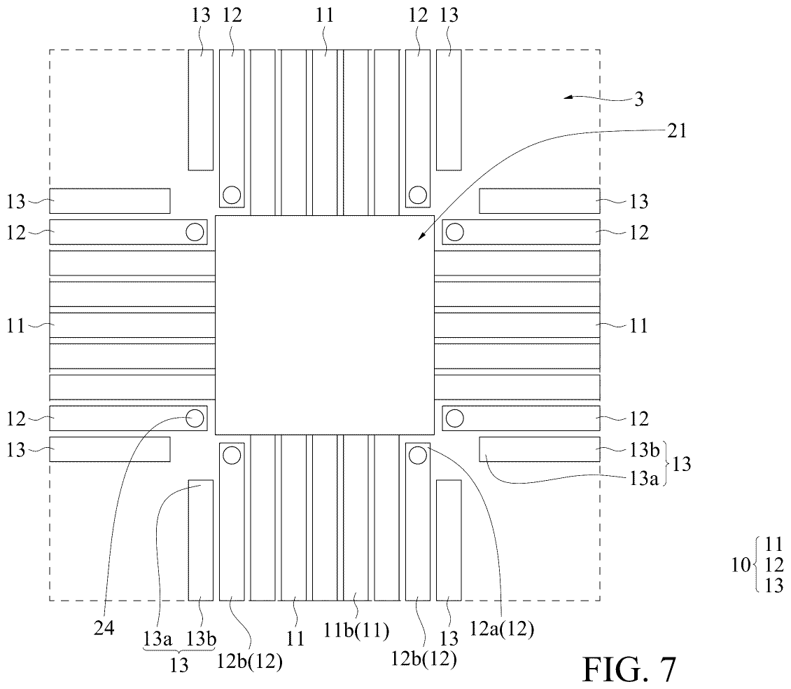

Please refer to FIG. 5, FIG. 6, and FIG. 7. The first leads 11, the second leads 12, and the third leads 13 extend in a direction away from the die-bonding region 2. From a top view perspective, the lead frame may be divided into a lead region 3 and the die-bonding region 2. The lead region 3 surrounds the die-bonding region 2. The leads 10 are mainly configured at the lead region 3. Based on the connections between the lead 10 and the die 20, the leads 10 may be divided into three types, namely the first leads 11, the second leads 12, and the third leads 13. The first leads 11 extend outward from first ends 11a thereof which are located on the die-bonding region 2 to second ends 11b thereof which are located on the outer periphery of the lead region 3. The second leads 12 and the third leads 13 are completely located within the lead region 3, and each of the second leads 12 and the third leads 13 extends outward from the first end 12a/13a thereof which is adjacent to the die-bonding region 2 to the second end 12b/13b thereof which is located on the outer periphery of the lead region 3. The upper die 22 and the lower die 21 are correspondingly disposed on the die-bonding region.

In some embodiments, for the convenience of wire-bonding, the first ends 13a of the third leads 13 need to be disposed outside the metal wire bonding layer 23 to prevent wires 31 from being interfered by the metal wire bonding layer 23. The first ends 11a of the first leads 11 and the first ends 12a of the second leads 12 are disposed under the metal wire bonding layer 23. In other words, in some embodiments, from a top view perspective, the metal wire bonding layer 23 will shield the first ends 11a of the first leads 11 and the first ends 12a of the second leads 12, but still expose the first ends 13a of the third leads 13. Therefore, the length of each of the first leads 11 is greater than the length of each of the third leads 13, and the length of each of the second leads 12 is greater than the length of each of the third leads 13.

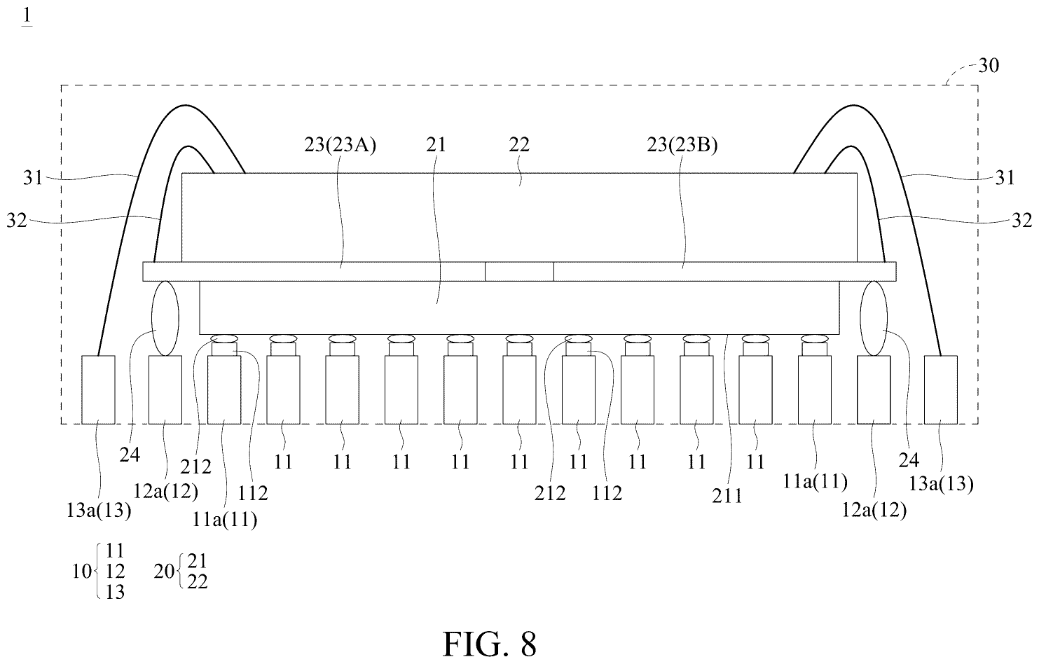

In some embodiments, the metal wire bonding layer 23 is a complete metal plate (as shown in FIG. 1) or a plurality of metal plates 23A, 23B disposed at intervals (as shown in FIG. 8). In some embodiments, the material of the metal plate may be but not limited to copper, gold, or alloy.

In some embodiments, in the case that the metal wire bonding layer 23 is a complete metal plate, since the second contacts 222 are wire-bonded to the metal wire bonding layer 23 through the wires 32, and the metal connecting pillars 24 are coupled between the metal wire bonding layer 23 and the corresponding second leads 12, the second contacts 222, the metal wire bonding layer 23, the metal connecting pillars 24, and the second leads 12 are at the same potential.

In some embodiments, in the case that the metal wire bonding layer 23 is the metal plate 23A and the metal plate 23B disposed at intervals, the second contacts 222 wire-bonded to the metal plate 23A through the wires 32 and the second contacts 222 wire-bonded to the metal plate 23B through the wires 32 are at different potentials, but the present disclosure is not limited thereto. The second contacts 222 wire-bonded to the metal plate 23A through the wires 32 and the second contacts 222 wire-bonded to the metal plate 23B through the wires 32 may also be at the same potential. In some embodiments, the second contacts 222 are a plurality of power contacts, a plurality of ground contacts, or a combination of the power contacts and the ground contacts. In some embodiments, the second contacts 222 wire-bonded to the metal plate 23A through the wires 32 and the second contacts 222 wire-bonded to the metal plate 23B through the wires 32 are the ground contacts, but the present disclosure is not limited thereto. In some other embodiments, all of the second contacts 222 wire-bonded to the metal plate 23A through the wires 32 and the second contacts 222 wire-bonded to the metal plate 23B through the wires 32 may also be the power contacts or the ground contacts.

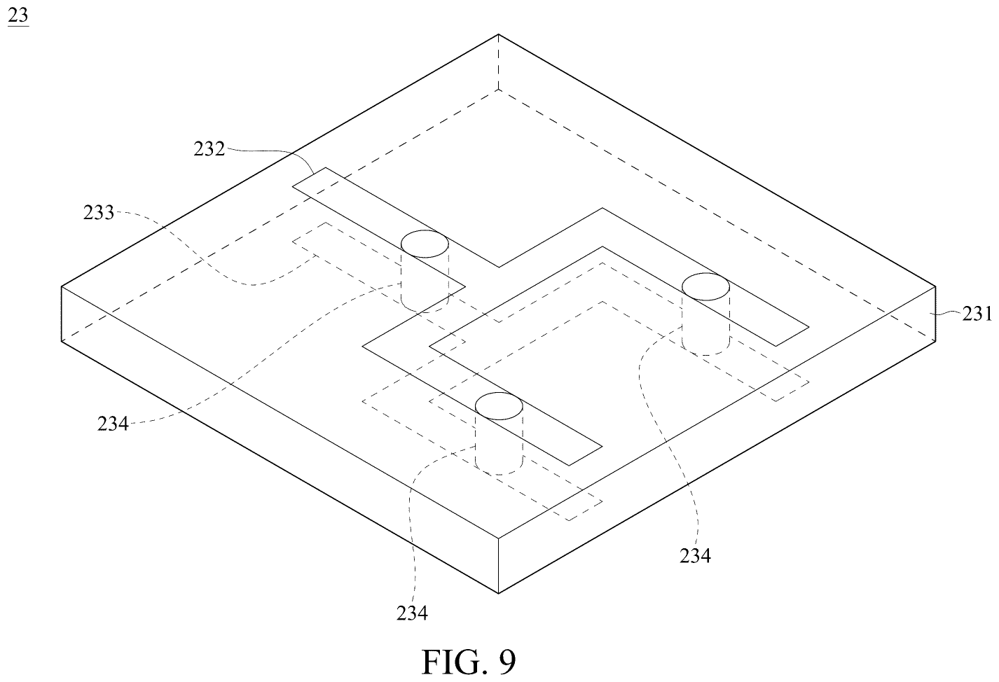

Please refer to FIG. 1 and FIG. 9. In some embodiments, the metal wire bonding layer 23 may also be a surface-patterned circuit board. Specifically, in some embodiments, the metal wire bonding layer 23 comprises an insulating layer 231, a first conductive trace 232, a second conductive trace 233, and a plurality of conductive vias 234. The first conductive trace 232 is on the upper surface of the insulating layer 231, wherein the second contacts 222 are wire-bonded to the first conductive trace 232 through the wires 32. The second conductive trace 233 is on the lower surface of the insulating layer 231 and is coupled to the metal connecting pillars 24. The conductive vias 234 penetrate the insulating layer 231 and are coupled between the first conductive trace 232 and the second conductive trace 233. In some embodiments, the first conductive trace 232 and the second conductive trace 233 may be a metal plate.

In some embodiments, the material of the metal connecting pillars 24 may be but is not limited to copper, gold or alloy. In some embodiments, the heights of the metal connecting pillars 24 may be dynamically adjusted according to the desired distance between the metal wire bonding layer 23 and the second leads 12. In some embodiments, the width of each of the metal connecting pillars 24 may be dynamically adjusted according to user demands; furthermore, the width of each of the metal connecting pillars 24 may be different, and the widths of the second leads 12 may also be dynamically adjusted according to the widths of the metal connecting pillars 24. In some embodiments, the metal connecting pillars 24 are disposed at the edge of the metal wire bonding layer 23, but the present disclosure is not limited thereto. The metal connecting pillars 24 may be disposed at any portion of the metal wire bonding layer 23 in which the position of the metal connecting pillars 24 do not interfere with the position of the lower die 21.

In some embodiments, each of the flip-chip solder pads 112 is directly soldered to a corresponding one of the bumps 212 along a vertical direction, but the present disclosure is not limited thereto. In some embodiments, the flip-chip solder pad 112 may be but not limited to a solder ball. In some embodiments, the flip-chip solder pads 112 may be but not limited to be respectively disposed on the first ends 11a of the first leads 11 by electroplating, and the material of the flip-chip solder pads 112 may be but not limited to copper, aluminum, or tin. In some embodiments, the positions of the flip-chip solder pads 112 on the first ends 11a of the first leads 11 may be but not limited to be determined through automated optical inspection (AOI) such as 3D AOI or 2D AOI. In some embodiments, the size of each of the flip-chip solder pads 112 is identical.

In some embodiments, the bump 212 may be but not limited to a solder ball or a copper pillar. In some embodiments, the bumps 212 may be but not limited to be disposed on the active surface 211 of the lower die 21 by ball mounting, solder paste printing, or electroplating. In some embodiments, the bumps 212 may be but not limited to be eutectically bonded to the flip-chip solder pads 112. In some embodiments, the size of each of the bumps 212 is identical. In some embodiments, the bumps 212 are configured to transmit high-speed signals, but the present disclosure is not limited thereto. The bumps 212 may also be configured to transmit low-speed signals.

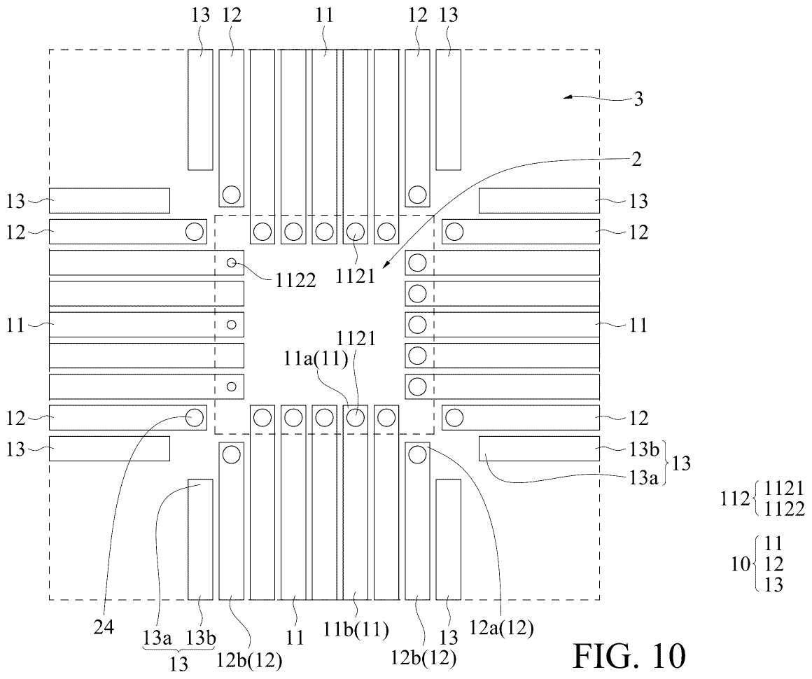

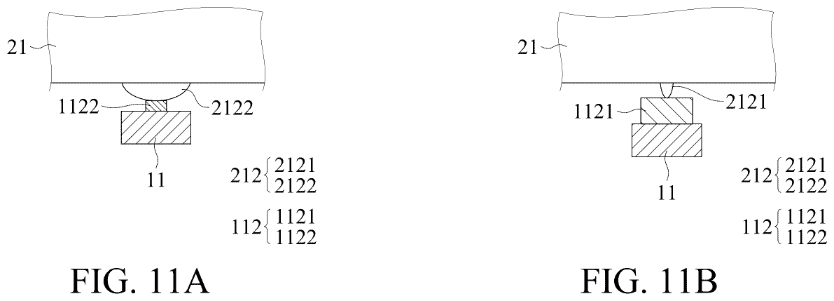

Please refer to FIG. 10 to FIG. 11B. In some embodiments, the flip-chip solder pads 112 comprise a plurality of first solder pads 1121 and a plurality of second solder pads 1122. The bumps 212 comprise a plurality of first bumps 2121 and a plurality of second bumps 2122. The size of the first solder pads 1121 is greater than the size of the second solder pads 1122, and the size of the first bumps 2121 is less than the size of the second bumps 2122. That is, in some embodiments, the width and height of the first solder pads 1121 are respectively greater than the width and height of the second solder pads 1122, and the width and height of the first bumps 2121 are respectively less than the width and height of the second bumps 2122. In order to ensure that all the bumps 212 can be successfully soldered to the respective flip-chip solder pads 112 at the same time and also in order to consider the balance issue between the leads 10 and the lower die 21 after the bumps 212 are soldered to the flip-chip solder pads 112, each of the first solder pads 1121 is configured to be directly soldered to a corresponding one of the first bumps 2121 and each of the second solder pads 1122 is configured to be directly soldered to a corresponding one of the second bumps 2122.

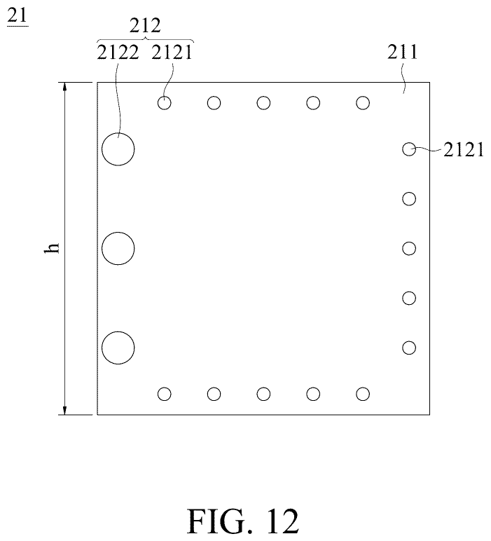

Please refer to FIG. 12. In some embodiments, because the size of the first bump 2121 is different from the size of the second bump 2122, under a same side length h of the die 20, the number of the first bumps 2121 that can be disposed on the active surface 211 of the lower die 21 will also be different from the number of the second bumps 2122 that can be disposed on the active surface 211 of the lower die 21. Please refer to FIG. 10 and FIG. 12. For example, assume that the side length h of the left side of the lower die 21 and the side length h of the right side of the lower die 21 shown in FIG. 12 are equal, because the size of the first bumps 2121 is less than the size of the second bumps 2122, five first bumps 2121 can be disposed on the right side of the lower die 21 while only three second bumps 2122 can be disposed on the left side of the lower die 21. It is realized that, the first leads 11 connected to the lower die 21 shown in FIG. 12 are the first leads 11 shown in FIG. 10. In correspondence to the positions of the second bumps 2122 of the lower die 21 shown in FIG. 12, only three of the first leads 11 on the left side of FIG. 10 are provided with the second solder pads 1122, that is, two of the first leads 11 on the left side of FIG. 10 are not provided with the flip-chip solder pads 112. In other words, in some embodiments, not all of the first leads 11 are provided with the flip-chip solder pads 112.

In some embodiments, the size of the second bump 2122 is greater than the size of the first bump 2121, thus facilitating in that the current of the lower die 21 flowing out from the second bump 2122. Therefore, in some embodiments, the second bumps 2122 are configured to transmit power signals, but the present disclosure is not limited thereto. In some other embodiments, the second bumps 2122 may also be configured to transmit differential signals or ground signals. In some embodiments, the first bumps 2121 may be but not limited to be configured to transmit differential signals or ground signals.

From the above, it can be seen that the first leads 11 of the semiconductor device 1 do not need to be connected to the lower die 21 through wire bonding as that applied in wire bonding packages known to the inventor. Instead, according to some embodiments, the first leads 11 are connected to the bumps 212 of the lower die 21 through the flip-chip solder pads 112. Therefore, the signal and power integrity of the lower die 21 are not limited by the impedance of the wires. Additionally, the length of the wires 32 connecting the upper die 22 with the metal wire bonding layer 23 are less than the length of the wires 31 connecting the upper die 22 with the third leads 13. Therefore, as compared with the wires 31, the wires 32 have smaller impedance and are less susceptible to power ripples. On the other hand, it is also realized that, in wire bonding packages known to the inventor, the die is directly wire-bonded to the leads (similar to the way that the upper die 22 is directly wire-bonded to the third leads 13 through the wires 31). As a result, as compared with the relevant arts known to the inventor, the upper die 22 is also less affected by the power ripples, resulting in higher signal and power integrity.

Furthermore, the metal wire bonding layer 23 can be regarded as a metal shield for the lower die 21, and thus the metal wire bonding layer 23 further has an electromagnetic shielding function for the lower die 21. Therefore, the configuration of the metal wire bonding layer 23 can reduce the electromagnetic interference applied to the lower die 21.

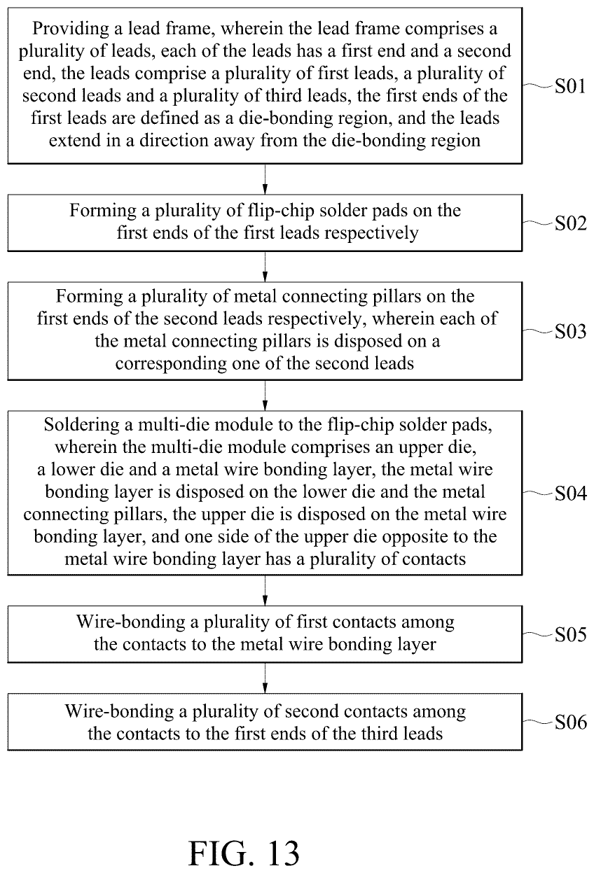

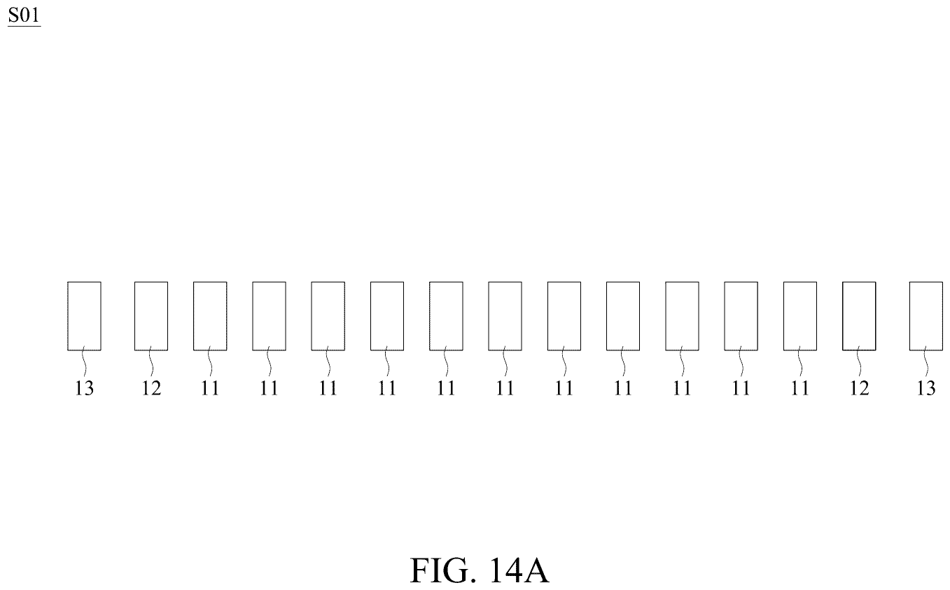

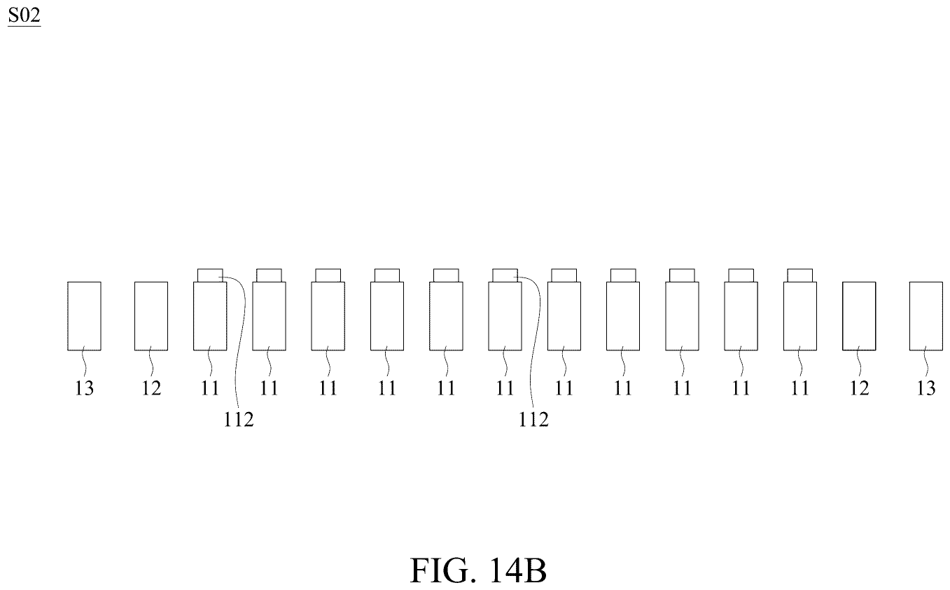

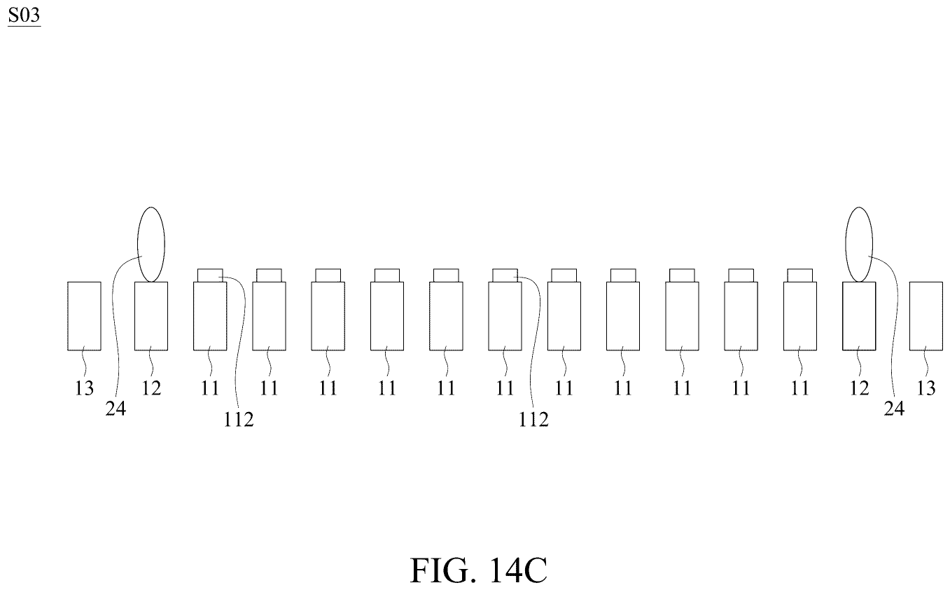

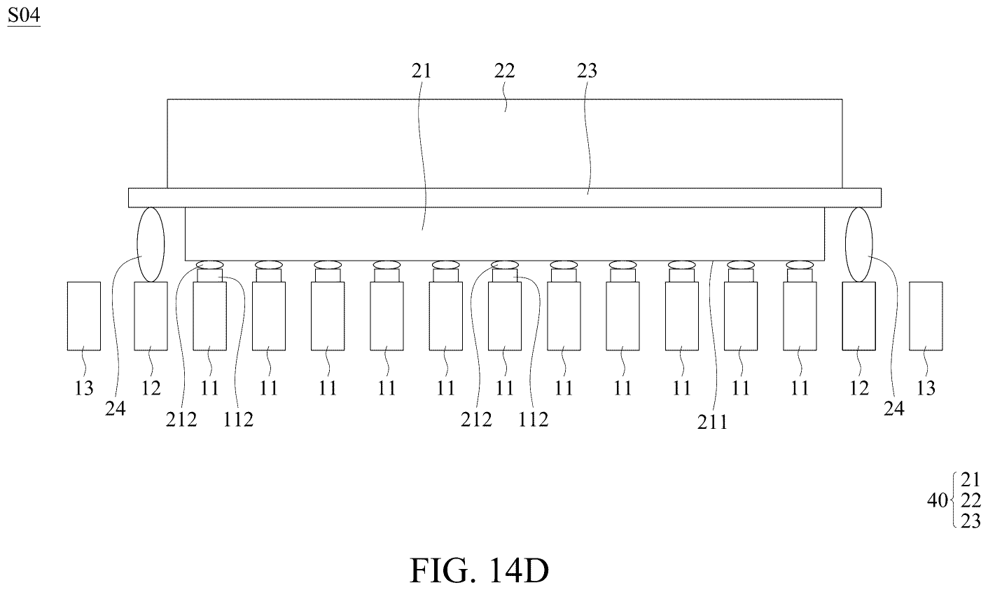

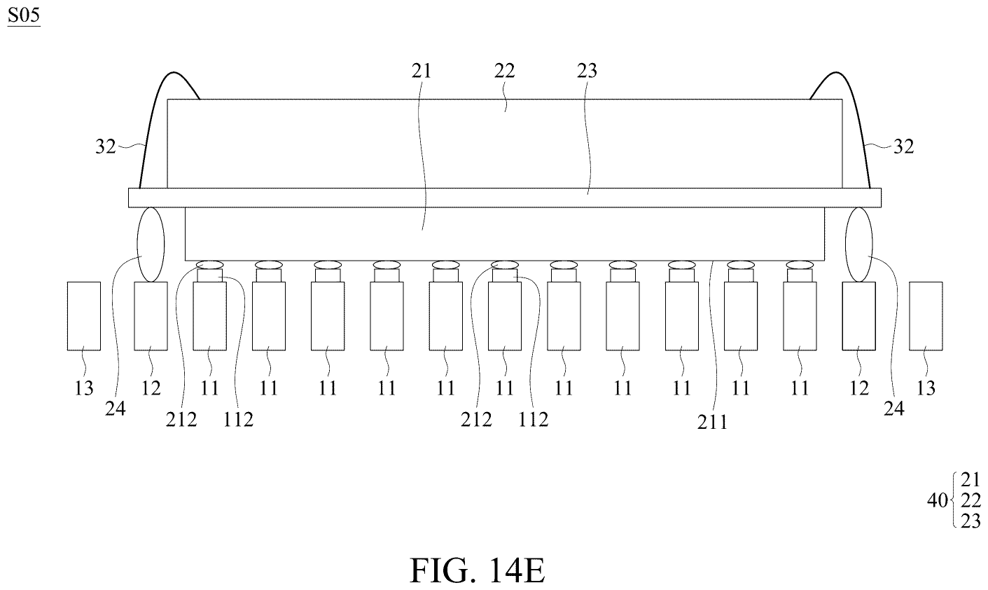

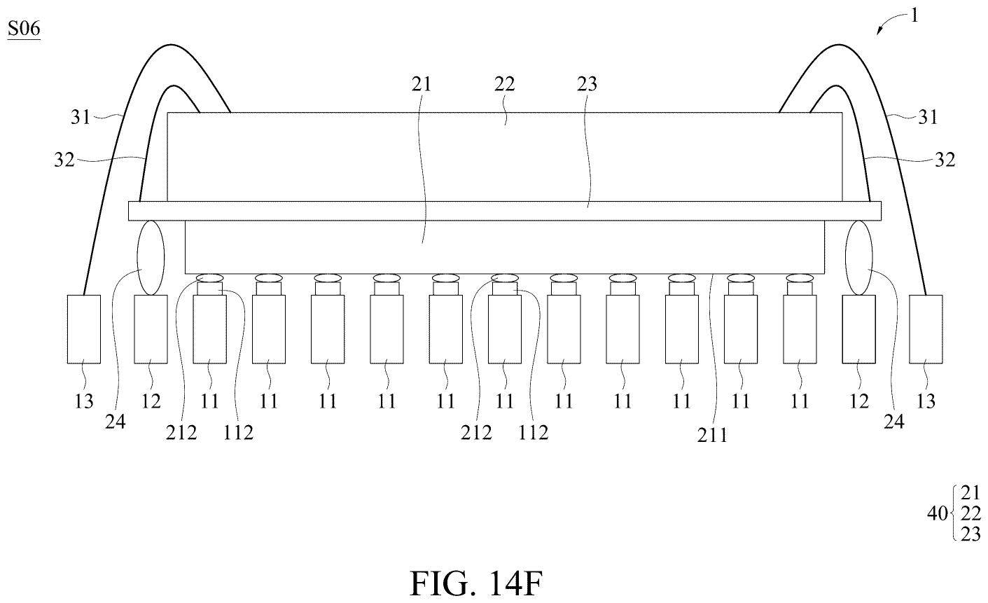

FIG. 13 illustrates a flowchart of an embodiment of a manufacturing method of semiconductor device. FIG. 14A to FIG. 14F illustrate schematic views of the steps of the embodiment of the method of semiconductor device. Please refer to FIG. 1, FIG. 6 and FIG. 13 to FIG. 14F. First, a lead frame is provided (step S01) (as shown in FIG. 14A). The lead frame comprises a plurality of leads. Each of the leads has a first end 11a/12a/13a and a second end 11b/12b/13b. The leads comprise a plurality of first leads 11, a plurality of second leads 12, and a plurality of third leads 13. The first ends 11a of the first leads 11 are defined as a die-bonding region 2. The leads extend in a direction away from the die-bonding region 2. Next, a plurality of flip-chip solder pads 112 are respectively formed on the first ends 11a of the first leads 11 (step S02) (as shown in FIG. 14B). Next, a plurality of metal connecting pillars 24 are respectively formed on the first ends 12a of the second leads 12 (step S03) (as shown in FIG. 14C). Each of the metal connecting pillars 24 is disposed on a corresponding one of the second leads 12. Then, a multi-die module 40 is soldered to the flip-chip solder pads 112 (step S04) (as shown in FIG. 14D). The multi-die module 40 comprises an upper die 22, a lower die 21, and a metal wire bonding layer 23. The metal wire bonding layer 23 is disposed on the lower die 21 and the metal connecting pillars 24. The upper die 22 is disposed on the metal wire bonding layer 23. One side of the upper die 22 opposite to the metal wire bonding layer 23 has a plurality of contacts. Last, a plurality of second contacts 222 among the contacts are wire-bonded to the metal wire bonding layer 23 through wires 32 (step S05) (as shown in FIG. 14E), and a plurality of first contacts 221 among the contacts are wire-bonded to the first ends 13a of the third leads 13 through wires 31 (step S06) (as shown in FIG. 14F).

In some embodiments, the steps of soldering the multi-die module 40 to the flip-chip solder pads 112 comprise: forming a plurality of bumps 212 corresponding to the positions of the flip-chip solder pads 112 on an active surface 211 of the lower die 21; directly contacting the bumps 212 on the lower die 21 to the flip-chip solder pads 112 respectively; and performing a reflow procedure so that each of the flip-chip solder pads 112 is directly soldered to a corresponding one of the bumps 212.

In some embodiments, the manufacturing method of the semiconductor device 1 further comprises, after step S06, forming a package 30 to enclose the lead frame, the multi-die module 40 and the metal connecting pillars 24.

In some embodiments, the manufacturing method of the semiconductor device 1 further comprises immersing the tops of the bumps 212 into a flux so that the flux is adhered to the bumps 212 after forming the bumps 212 corresponding to the positions of the flip-chip solder pads 112 on the active surface 211 of the lower die 21.

In some embodiments, the flip-chip solder pads 112 comprises a plurality of first solder pads 1121 and a plurality of second solder pads 1122. The bumps 212 comprise a plurality of first bumps 2121 and a plurality of second bumps 2122. The size of the first solder pads 1121 is greater than the size of the second bonding pads 1122, and the size of the first bumps 2121 is less than the size of the second bumps 2122. In some embodiments, when each of the flip-chip solder pads 112 is directly soldered to a corresponding one of the bumps 212, each of the first bumps 2121 corresponds to a corresponding one of the first solder pads 1121, and each of the second bumps 2122 corresponds to a corresponding one of the second solder pads 1122.

In some embodiments, the steps of forming the bumps 212 corresponding to the positions of the flip-chip solder pads 112 on the active surface 211 of the lower die 21 comprise: forming a photoresist layer on the active surface 211 of the lower die 21; forming a plurality of first openings and a plurality of second openings on the photoresist layer, wherein the opening area of any of the first openings is smaller than the opening area of any of the second openings; filling a metal into the first openings and the second openings; removing the photoresist layer; and performing a reflow procedure so that the metal in each of the first openings forms the corresponding one of the first bumps 2121 and the metal in each of the second openings forms the corresponding one of the second bumps 2122.

In some embodiments, the distribution position or the distribution number of the leads on one of the sides of the lead frame is different from the distribution position or the distribution number of the leads on the other sides of the lead frame, thus allowing the user to identify the direction in which the lead frame and the semiconductor device 1 comprising the lead frame are disposed.

To sum up, any embodiment of the semiconductor device 1 or the manufacturing method of the semiconductor device 1 can reduce the noise on the power-ground loop while providing electromagnetic interference (EMI) shielding. In other words, in some embodiments, the signal and power integrity of the lower die 21 are not limited by the impedance of the wires. Additionally, as compared with the relevant arts known to the inventor, the upper die 22 is also less affected by the power ripples, resulting in higher signal and power integrity. Therefore, the semiconductor device 1 can be applied to chip packages containing high-speed signals with stringent requirements on signal and power integrity.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A semiconductor device, comprising:
a plurality of leads, wherein each of the leads has a first end and a second end, the leads comprise a plurality of first leads, a plurality of second leads, and a plurality of third leads, the first ends of the first leads are defined as a die-bonding region, and the first leads, the second leads and the third leads extend in a direction away from the die-bonding region;
a lower die correspondingly disposed on the die-bonding region, wherein the lower die has an active surface;
a plurality of bumps disposed on the active surface;
a plurality of flip-chip solder pads respectively disposed on the first ends of the first leads, wherein the lower die is directly soldered to the flip-chip solder pads through the bumps so as to be electrically connected to the first leads;
an upper die corresponding to the die-bonding region and disposed on the lower die, wherein one side of the upper die opposite to the lower die has a plurality of first contacts and a plurality of second contacts, and the first contacts are wire-bonded to the first ends of the third leads;
a plurality of metal connecting pillars respectively standing on the first ends of the second leads; and
a metal wire bonding layer disposed between the upper die and the lower die and disposed on the metal connecting pillars, wherein the second contacts are wire-bonded to the metal wire bonding layer.

2. The semiconductor device according to claim 1, wherein the metal wire bonding layer is a metal plate.

3. The semiconductor device according to claim 1, wherein the metal wire bonding layer comprises:
an insulating layer;
a first conductive trace on an upper surface of the insulating layer, wherein the second contacts are wire-bonded to the first conductive trace;
a second conductive trace on a lower surface of the insulating layer and coupled to the metal connecting pillars; and
a plurality of conductive vias penetrating the insulating layer and coupled between the first conductive trace and the second conductive trace.

4. The semiconductor device according to claim 1, wherein the second contacts are a plurality of power contacts, a plurality of ground contacts, or a combination of the power contacts and the ground contacts.

5. The semiconductor device according to claim 1, further comprising:
a package enclosing the leads, the lower die, the bumps, the flip-chip solder pads, the upper die, the metal connecting pillars, and the metal wire bonding layer.

6. The semiconductor device according to claim 1, wherein the flip-chip solder pads comprise a plurality of first solder pads and a plurality of second solder pads, the bumps comprise a plurality of first bumps and a plurality of second bumps, each of the first solder pads is configured to be directly soldered to a corresponding one of the first bumps, each of the second solder pads is configured to be directly soldered to a corresponding one of the second bumps, a height of any of the second solder pads is less than a height of any of the first solder pads, and a height of any of the second bumps is greater than a height of any of the first bumps.

7. The semiconductor device according to claim 1, wherein a length of each of the first leads is greater than a length of each of the third leads, and a length of each of the second leads is greater than the length of each of the third leads.

8. A manufacturing method of semiconductor device, comprising:
providing a lead frame, wherein the lead frame comprises a plurality of leads, each of the leads has a first end and a second end, the leads comprise a plurality of first leads, a plurality of second leads and a plurality of third leads, the first ends of the first leads are defined as a die-bonding region, and the leads extend in a direction away from the die-bonding region;
forming a plurality of flip-chip solder pads on the first ends of the first leads respectively;
forming a plurality of metal connecting pillars on the first ends of the second leads respectively, wherein each of the metal connecting pillars is disposed on a corresponding one of the second leads;
soldering a multi-die module to the flip-chip solder pads, wherein the multi-die module comprises an upper die, a lower die and a metal wire bonding layer, the metal wire bonding layer is disposed on the lower die and the metal connecting pillars, the upper die is disposed on the metal wire bonding layer, and one side of the upper die opposite to the metal wire bonding layer has a plurality of contacts;
wire-bonding a plurality of first contacts among the contacts to the metal wire bonding layer; and
wire-bonding a plurality of second contacts among the contacts to the first ends of the third leads.

9. The manufacturing method of semiconductor device according to claim 8, wherein the steps of soldering the multi-die module to the flip-chip solder pads comprises:
forming a plurality of bumps corresponding to the positions of the flip-chip solder pads on an active surface of the lower die;
contacting the bumps on the lower die to the flip-chip solder pads respectively; and
performing a reflow procedure so that each of the flip-chip solder pads is directly soldered to a corresponding one of the bumps.

10. The manufacturing method of semiconductor device according to claim 8, wherein the second contacts are a plurality of power contacts, a plurality of ground contacts, or a combination of the power contacts and the ground contacts.

11. The manufacturing method of semiconductor device according to claim 9, wherein the flip-chip solder pads comprise a plurality of first solder pads and a plurality of second solder pads, the bumps comprise a plurality of first bumps and a plurality of second bumps, each of the first solder pads is configured to be directly soldered to a corresponding one of the first bumps, each of the second solder pads is configured to be directly soldered to a corresponding one of the second bumps, a height of any of the second solder pads is less than a height of any of the first solder pads, and a height of any of the second bumps is greater than a height of any of the first bumps.

12. The manufacturing method of semiconductor device according to claim 8, wherein a length of each of the first leads is greater than a length of each of the third leads, and a length of each of the second leads is greater than the length of each of the third leads.

13. The manufacturing method of semiconductor device according to claim 8, further comprising:
forming a package to enclose the lead frame, the multi-die module, and the metal connecting pillars.
